(19) United States
(12) Patent Application Publication
(10) Pub. No.: US 2001/0005635 A1
(43) Pub. Date: Jun. 28, 2001

(54) Ashing method and method of producing wired device

(76) Inventor: Hideo Kitagawa, Utsunomiya-shi (JP)

Correspondence Address: FITZPATRICK CELLA HARPER & SCINTO, 30 ROCKEFELLER PLAZA, NEW YORK, NY, 10112, US

(21) Appl. No.: 09/735,808

(22) Filed: Dec. 14, 2000

(30) Foreign Application Priority Data
Dec. 20, 1999 (JP) 11-361253

(51) Int. Cl. H01L 21/302

(52) U.S. Cl. 438/710; 438/712

(57) ABSTRACT

For ashing without degradation of film quality of an organic low-dielectric-constant film of a base, there is provided a method of ashing an organic resist pattern formed on an interlayer insulating film, which includes an organic low-dielectric-constant film at least in part over an article, wherein the ashing is carried out using a plasma of a mixed gas of oxygen and nitrogen. The mixing ratio of nitrogen and oxygen is determined such that the content of oxygen is greater than 0 vol % and not more than 10 vol %.

### BACKGROUND OF THE INVENTION

1. Field of the Invention

The present invention relates to ashing technology for removing an organic resist pattern after use and, more particularly, to an ashing method and a method of producing a wired device, which are capable of ashing the organic resist pattern whose base is an interlayer insulating film including an organic film of a low dielectric constant (hereinafter referred to “organic low-dielectric-constant film”), without degradation of the quality of the organic low-dielectric-constant film.

2. Related Background Art

With the development of integration and fine structure formation in LSI, the problem of signal delay in wiring becomes more pronounced. A solution to the problem is a method of replacing at least a part of an interlayer insulating film with a film with a dielectric constant lower than SiO₂, the so-called Low-k film.

The conventional ashing of a resist pattern on an interlayer insulating film including an organic low-dielectric-constant film was conducted mainly using an oxygen plasma. For example, Japanese Patent Application Laid-Open No. 9-153483 discloses a method of carrying out ashing at a good selectivity between a resist and an organic low-dielectric-constant film by cooling a substrate to below room temperature, using an oxygen plasma. This method utilizes a difference in the activation energy of a reaction to oxygen radical between the resist and the organic low-dielectric-constant film.

FIG. 1 shows an example of temperature dependency of ashing rate by an oxygen plasma of a resist and an organic low-dielectric-constant film. FIG. 1 is a so-called Arrhenius's plot in which the axis of abscissa indicates 1000/T (T is absolute temperature (K)) and the axis of ordinate the ashing rate (in logarithmic representation), for obtaining the activation energy. When determined using the data shown in FIG. 1, the activation energy of ashing of the resist by the oxygen plasma is 0.17 eV, while the activation energy of the organic low-dielectric-constant film is 0.3 eV. Further, the selectivity of a resist to an organic low-dielectric-constant film at room temperature (=ashing rate of resist/ashing rate of organic low-dielectric-constant film) is approximately 6, and the substrate needs to be cooled to substrate temperatures of −50° C. or less in order to achieve the selectivity of not less than 10. Further, since the ashing rate of an organic low-dielectric-constant film is about 40 nm/min to 50 nm/min even below room temperature, the amount of loss of the organic low-dielectric-constant film is non-negligible. Further, since the process is carried out in an oxygen plasma, oxygen atoms will diffuse into the organic low-dielectric-constant film, while the film is ashed by a small amount. This oxygen may be desorbed during a subsequent film-forming process to cause abnormal film formation.

In order to solve the above problem, Japanese Patent Application Laid-Open No. 10-209118 discloses the method of carrying out ashing by a plasma of a mixed gas of nitrogen and hydrogen. Since this method does not use oxygen, it is completely free of the degradation of film quality due to the diffusion of oxygen atoms into the organic low-dielectric-constant film. This method, however, needs to use the hydrogen gas, which is a combustible gas, and thus handling of the gas is not easy. Further, an apparatus for this method also needs to be equipped with some explosion-proof means, which adds complexity to the structure of apparatus. It is also possible to use ammonia (NH₃) or hydrazine (N₂H₄) instead of hydrogen, but these gases possess toxicity and thus need to be handled with more care than hydrogen.

As described above, in the ashing of a resist above an organic low-dielectric-constant film with an oxygen plasma, considerably low temperatures are necessary for attainment of a high selectivity and thus the cooling system becomes large in scale.

In addition, oxygen will inevitably diffuse into the organic low-dielectric-constant film and, for example, if the subsequent step is a film-forming process of a tungsten plug, abnormal film formation will occur because of the desorption of the oxygen during the film-forming process.

### SUMMARY OF THE INVENTION

An object of the present invention is to provide an ashing method and a production method of a wired device that are capable of removing a resist pattern and a side-wall-protecting film remaining after etching by adding a small amount of oxygen to nitrogen so as to keep the selectivity high with regard to an organic low-dielectric-constant film.

### BRIEF DESCRIPTION OF THE DRAWINGS

FIG. 1 is a graph showing the substrate temperature dependency of ashing rates of an organic low-dielectric-constant film and a photoresist;

FIGS. 2A, 2B, 2C and 2D are views showing the process flow of etching of an organic low-dielectric-constant film;

FIGS. 3A and 3B are diagrams showing the structural formulas of organic low-dielectric-constant films used in the present invention; and

FIG. 4 is a graph showing gas ratio dependency of ashing rates of an organic low-dielectric-constant film and a photoresist in the gas system of the present invention.

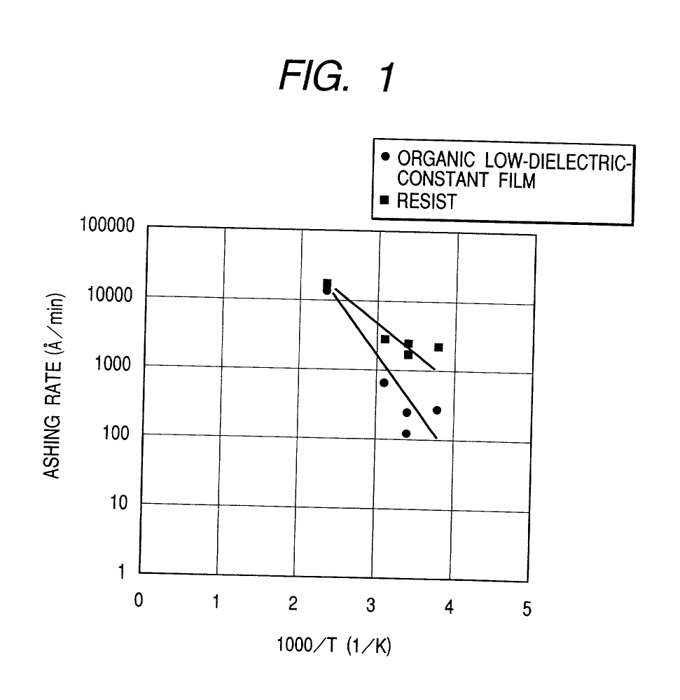

### DETAILED DESCRIPTION OF THE PREFERRED EMBODIMENTS

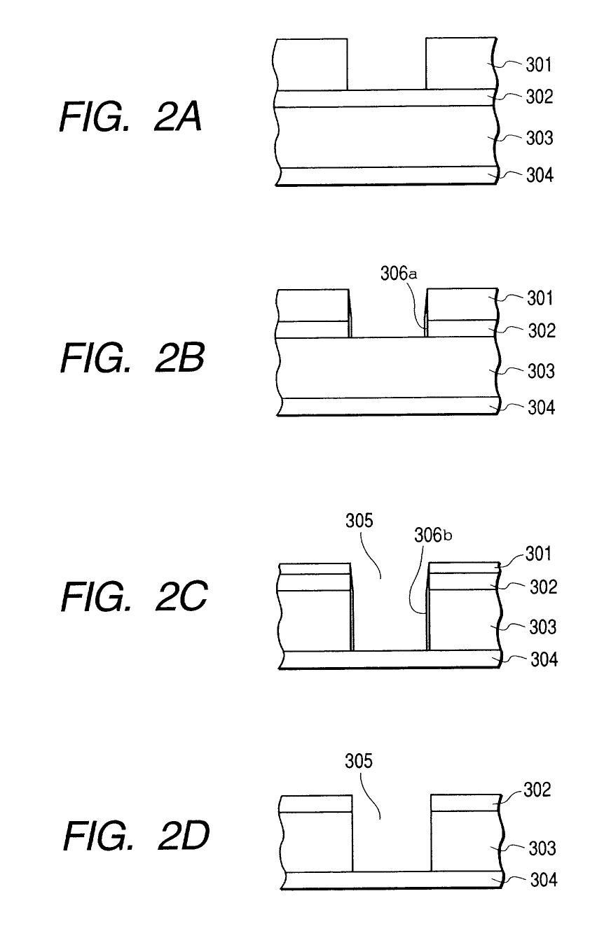

FIGS. 2A to 2D are schematic views for explaining a method of producing a wired device, including the ashing method according to the present invention.

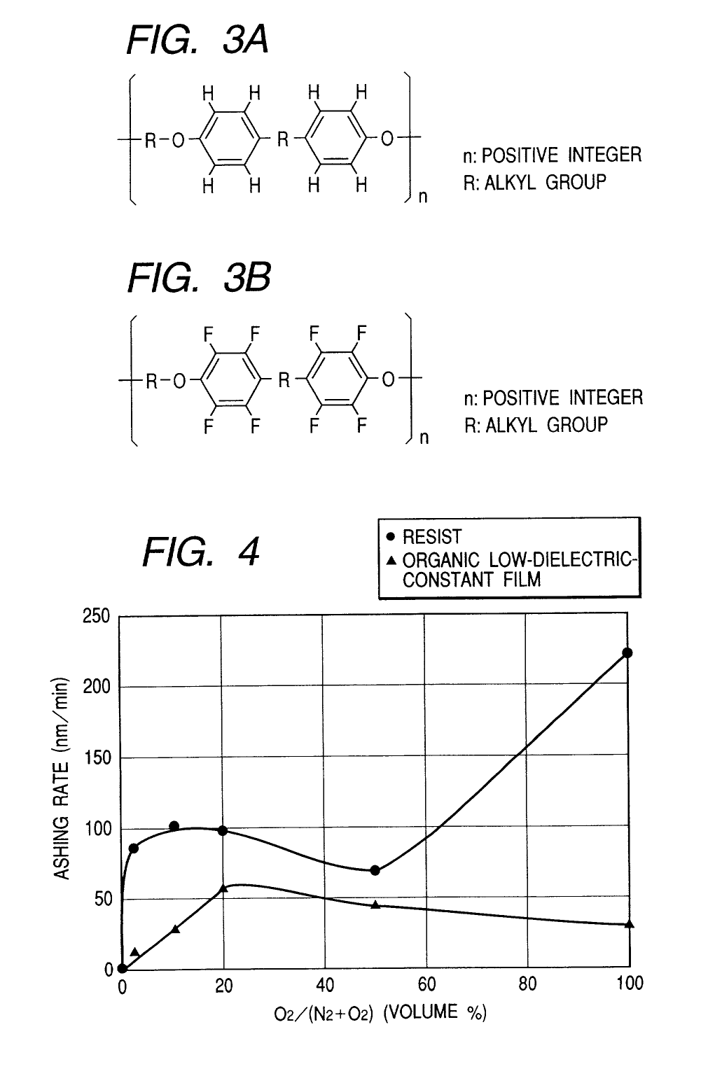

A wire 304, an organic low-dielectric-constant film 303, and an inorganic insulating film 302 are formed over a substrate such as a silicon wafer or the like. Here the wire 304 may be a metal containing at least one selected from Cu, Al, W, Ti, Ta, and so on, or a nitride or a silicide of the metal. The organic low-dielectric-constant film 303 is an organic insulator (organic dielectric) having a dielectric constant (or permittivity or relative permittivity) lower than SiO₂ and is preferably polyaryl ether or polyfluoroaryl ether having the structure as illustrated in FIG. 3A or 3B.

The inorganic insulating film 302 is preferably either one selected from silicon oxide, silicon nitride, and silicon oxynitride, which are formed by CVD or coating and may optionally be doped with fluorine.

Then a photosensitive resin is applied and prebaked and thereafter the photosensitive resin is partially exposed to excimer laser light such as KrF, ArF, F₂, or the like to form a latent image pattern. After that, the photosensitive resin is developed to form a resist mask 301 as illustrated in FIG. 2A. Since this developed resist mask 301 serves only as an etching mask after this step, it may be either one still maintaining its photosensitivity or one having lost its photosensitivity.

Then etching of the inorganic insulating film 302 as a hard mask is carried out using a fluorocarbon-containing gas like a mixed gas of C₄F₈/O₂/Ar, as illustrated in FIG. 2B.

At this time, a side-wall-protecting film 306a containing fluorocarbon is formed on a side wall of the recess 305 as a wire trench and/or a via hole, thereby preventing side etching of the inorganic insulating film 302 as the hard mask.

Then etching of the organic insulating film 303 is carried out using oxygen gas or a mixed gas of N₂/H₂, as illustrated in FIG. 2C. At this time, a side-wall-protecting film 306b containing C, H, and N is also formed on the side surface in the recess 305 of the organic insulating film 303. At this time, the upper part of the resist mask 301 is also etched away.

Then ashing is conducted using a plasma of a mixed gas of oxygen and nitrogen to remove the remaining resist mask 301 and side-wall-protecting films 306a, 306b, as illustrated in FIG. 2D.

Then wet cleaning or the like is carried out as occasion demands. Thereafter, a barrier metal such as TiN, TaN, TiW, TaW, WN, Ti, Ta, W, or the like is formed in the recess 305, and pure Cu, pure Al or a metal containing Cu or Al as a main component is formed thereon. Then unnecessary portions are removed by CMP or by etching.

The above steps are repeated at least once to fabricate a wired device.

The wired device is preferably used in electron devices such as LSIs, flat panel displays, and so on.

The ashing for obtaining the structure of FIG. 2D will be detailed hereinafter.

FIG. 4 shows the gas ratio dependency of ashing rates of a photoresist and an organic low-dielectric-constant film in an N₂/O₂-based plasma. The axis of abscissa indicates the ratio (proportion) of oxygen in a mixture of nitrogen and oxygen by volume percentage. As is seen from FIG. 4, the ashing rates of the photoresist and the organic low-dielectric-constant film both are 0 at the oxygen ratio of 0 vol %, i.e., without addition of oxygen. With increase in the oxygen ratio, the ashing rate of the organic low-dielectric-constant film gradually increases, reaches a maximum at the oxygen ratio of about 20 vol %, and then gradually decreases thereafter. On the other hand, the photoresist demonstrates such complicated behavior that the ashing rate thereof rapidly increases with addition of oxygen even in small ratios of 1 to 3 vol %, reaches a maximum at the oxygen ratio of about 10 vol %, gradually decreases down to a minimum at the oxygen ratio of about 50 vol %, and thereafter increases until the oxygen ratio of 100 vol % is reached. High selectivities for the resist (the ashing rate of the resist/the ashing rate of the organic low-dielectric-constant film) are attained when the oxygen ratio is 100 vol % and when a small amount of oxygen is added to nitrogen. When the oxygen ratio is 100 vol %, the selectivity is about 7, so as to accomplish both the relatively high ashing rate and selectivity. However, the ashing rate of the organic low-dielectric-constant film is considerably high, about 30 nm/min, and will cause the so-called poisoned via, which is the phenomenon that the organic low-dielectric-constant film exposed in the side wall of a via hole is etched in the lateral direction. Further, since the ashing is carried out under the condition of high oxygen ratio, degradation of film quality will occur because of oxygen taken into the organic film and abnormal embedding of a metal wire into the hole will further occur in the subsequent film-forming step because of desorption of the oxygen taken into the film.

On the other hand, since the oxygen ratios are small under the condition of addition of oxygen in small amounts, the above problem of degradation of film quality will not arise at all. Further, there is also the advantage that controllability is very high over occurrence of a poisoned via, because the ashing rates of the organic low-dielectric-constant film are very small, not more than 10 nm/min. Under the condition of addition of oxygen 3 vol %, the ashing rate of the resist is considerably low, about 80 nm/min. However, since only small amounts of the photoresist mask and the side-wall-protecting films remain on the substrate surface after the etching of the organic low-dielectric-constant film, as also shown in FIG. 2C, the residues can be removed in a short period of time even at a low ashing rate. Therefore, the content of oxygen is preferably higher than 0 vol % and not more than 10 vol %. The content of oxygen is more preferably 3 vol % to 10 vol %.

The plasma processing method of the present invention will be described below in further detail with reference to examples thereof, but it is noted that the present invention is by no means intended to be limited to the examples.

### EXAMPLE 1

The first example of the present invention is an example using FLARE (trade name) available from Allied-Signal Inc., as the organic low-dielectric-constant film 303. First prepared was a silicon wafer having the cross-sectional structure illustrated in FIG. 2A. The thicknesses of the respective films were as follows: the thickness of the organic low-dielectric-constant film 303 was 700 nm; the thickness of the SiO₂ film 302 was 200 nm; the thickness of the photoresist mask 301 was 670 nm. The photoresist mask 301 was patterned so as to form holes of 0.2 μm throughout in the surface of the wafer. The wafer was set in an etching system (not shown) equipped with a surface-wave interfered plasma (hereinafter referred to as SIP) source such as described in Japanese Patent Application Laid-Open No. 11-40397. Then the inside of the processing chamber was evacuated to 1×10⁻³ Pa and thereafter reactive ion etching of the SiO₂ film as the hard mask was conducted. The etching conditions were as follows.

Gas species and flow rates: C₄F₈/O₂/Ar=15/5/180 sccm

Pressure: 3 Pa

Microwave power: 1.5 kW

RF bias power to substrate: 350 W

The etching was conducted under the above conditions for thirty seconds to remove all of portions of the SiO₂ film not covered by the mask. The end point of the etching was determined with emission of SiF (wavelength: 640 nm) and from intensity of the emission.

After completion of the etching of the SiO₂ film, the inside of the processing chamber was evacuated to 1× 10⁻³ Pa and thereafter reactive ion etching of the organic low-dielectric-constant film 303 was carried out. The etching conditions were as follows.

Gas species and flow rate: NH₃=200 sccm

Pressure: 3 Pa

Microwave power: 2.5 kW

RF bias power to substrate: 450 W

The etching was continued under the above conditions for sixty seconds to remove all of portions of the organic low-dielectric-constant film not covered by the mask. The end point of the etching was determined with emission of CN (wavelength: 388 nm) and from intensity of the emission. After completion of the etching, the wafer surface was checked by means of an SEM with the result that a small amount of the photoresist remaining on the surface of the hard mask and the side-wall-protecting films deposited inside the holes were observed.

Then the wafer was transferred into another chamber equipped with SIP, and cleaning by the plasma ashing was carried out. The process conditions were as follows.

Gas species and flow rates: N₂/O₂=194/6 sccm

Pressure: 100 Pa

Microwave power: 1.5 kW

Substrate temperature: −10° C.

Bias power to substrate: not applied

The plasma ashing was performed under the above conditions for thirty seconds. After completion of the ashing, the wafer surface was checked by means of an SEM with the result that neither the photoresist remaining on the hard mask surface nor the side-wall-protecting films deposited inside the holes was observed.

After completion of the ashing, the wafer was subjected to analysis of gases emitted during temperature rise by means of TDS (Thermal Desorption mass Spectroscopy) with the result that emission of O₂ or H₂O gas was not detected with heating up to 400° C.

Further, film formation of a TiN barrier metal by sputtering and film formation of tungsten by CVD were also carried out using another wafer subjected to the above cleaning and cross sections of the wafer were observed by means of an SEM to check the embedded state of the tungsten plugs with the result that no abnormal embedding was observed at all.

### EXAMPLE 2

The second example of the present invention is an example using SiLK (trade name) available from The Dow Chemical Co., as the organic low-dielectric-constant film 303. First prepared was a silicon wafer having the cross-sectional structure illustrated in FIG. 2A, as in Example 1. The thicknesses of the respective films were as follows: the thickness of the organic low-dielectric-constant film 303 was 600 nm; the thickness of the SiO₂ film 302 was 200 nm; the thickness of the photoresist mask 301 was 670 nm. The photoresist mask 301 was patterned so as to form holes of 0.2 μm throughout in the surface of the wafer. The wafer was set in an etching system (not shown) equipped with the SIP. Then the inside of the processing chamber was evacuated to 1×10⁻³ Pa and thereafter reactive ion etching of the SiO₂ film as the hard mask was conducted. The etching conditions were as follows.

Gas species and flow rates: C₄F₈/O₂/Ar=15/5/180 sccm

Pressure: 3 Pa

Microwave power: 1.5 kW

RF bias power to substrate: 350 W

The reactive ion etching was conducted under the above conditions for thirty seconds to remove all of portions of the SiO₂ film not covered by the mask. The end point of the etching was determined with emission of SiF (wavelength: 640 nm) and from intensity of the emission.

After completion of the etching of SiO₂, the inside of the processing chamber was evacuated to the vacuum of 1×10⁻³ Pa and thereafter the etching of the organic low-dielectric-constant film was carried out. The etching conditions were as follows.

Gas species and flow rate: NH₃=200 sccm

Pressure: 3 Pa

Microwave power: 2.5 kW

RF bias power to substrate: 450 W

The reactive ion etching was continued under the above conditions for fifty seconds to remove all of portions of the organic low-dielectric-constant film not covered by the mask. The end point of the etching was determined with emission of CN (wavelength: 388 nm) and from intensity of the emission. After completion of the etching, the wafer surface was checked by means of an SEM with the result that a small amount of the photoresist remaining on the surface of the hard mask and the side-wall-protecting films deposited inside the holes were observed.

Then the wafer was transferred into another chamber equipped with SIP and the plasma ashing was carried out. The process conditions were as follows.

Gas species and flow rates: N₂/O₂=194/6 sccm

Pressure: 100 Pa

Microwave power: 1.5 kW

Substrate temperature: −10° C.

Bias voltage to substrate: not applied

The plasma ashing was performed under the above conditions for thirty seconds. After completion of the ashing, the wafer surface was checked by means of an SEM with the result that neither the photoresist remaining on the hard mask surface and the side-wall-protecting films deposited inside the holes was observed.

After completion of the cleaning, the wafer was subjected to analysis of gases emitted during temperature rise by means of the TDS with the result that emission of O₂ or H₂O gas was not detected with heating up to 400° C.

Film formation of a TiN barrier metal by sputtering and film formation of W by CVD were also carried out using another wafer subjected to the above cleaning and cross sections of the wafer were observed with an SEM to check the embedded state of the W plugs with the result that no abnormal embedding was observed at all.

As described above, according to the present invention, by adding a small amount of oxygen to nitrogen, it becomes possible to remove a resist pattern and a side-wall protecting film after etching substantially with no etching of an organic low-dielectric-constant film.

What is claimed is:

1. A method of ashing a resist pattern formed on an insulating film comprising an organic insulator in an article, the method comprising performing ashing by the use of a plasma of a mixed gas of oxygen and nitrogen.

2. The ashing method according to claim 1, wherein the content of oxygen in the mixed gas is more than 0 vol % and not more than 10 vol %.

3. The ashing method according to claim 1, wherein the temperature of the article is not more than room temperature.

4. The ashing method according to claim 1, wherein the organic insulator is polyaryl ether or polyfluoroaryl ether.

5. A method of producing a wired device, comprising the steps of:
carrying out the ashing method as set forth in claim 1; and
forming a metal layer in a recess formed in the insulating film.

6. A method of producing a wired device, comprising the steps of:
forming a resist pattern on an insulating film comprising an organic insulator in an article; and
performing ashing by the use of a plasma of a mixed gas of oxygen and nitrogen.

7. The method according to claim 6, wherein the content of oxygen in the mixed gas is more than 0 vol % and not more than 10 vol %.

8. The method according to claim 6, wherein the temperature of the article is not more than room temperature.

9. The method according to claim 6, wherein the organic insulator is polyaryl ether or polyfluoroaryl ether.

10. A method of producing a wired device, comprising the steps of:
forming an insulating film comprising an organic insulator on a substrate;
forming a resist pattern on the insulating film;
forming a recess in the insulating film; and
ashing the resist pattern by the use of a plasma of a mixed gas comprising oxygen and nitrogen.
